(19) United States
(12) Patent Application Publication
(10) Pub. No.: US 2007/0125984 A1
(43) Pub. Date: Jun. 7, 2007

(54) Phosphors protected against moisture and LED lighting devices

(75) Inventors: Yongchi Tian, Princeton Junction, NJ (US); Perry Niel Yocom, Washington Crossing, PA (US); Liyou Yang, Plainsboro, NJ (US); Gerard Frederickson, Yardley, PA (US); Robert Simms, Cream Ridge, NJ (US)

Correspondence Address: PATENT DOCKET ADMINISTRATOR;LOWENSTEIN SANDLER P.C., 65 LIVINGSTON AVENUE, ROSELAND, NJ, 07068, US

(73) Assignee: Sarnoff Corporation

(21) Appl. No.: 11/455,560

(22) Filed: Jun. 19, 2006

Related U.S. Application Data
(60) Provisional application No. 60/741,307, filed on Dec. 1, 2005.

(51) Int. Cl. H01L 33/00; C09K 11/54

(52) U.S. Cl. 252/301.4 S; 428/403; 428/404; 252/301.6 S; 257/98; 313/503

(57) ABSTRACT

The present invention provides-a photoluminescent phosphor coated with a coating of oxide, the phosphor comprising (1) an inorganic phosphor chosen from (a) a metal thiogallate phosphor and (b) a metal sulfide phosphor and (2) a coating that comprises at least one layer having at least one oxides. The coated photoluminescent phosphor of the present invention is more resistant to water-induced degradation than when it is uncoated.

### CROSS-REFERENCE TO RELATED APPLICATION

This application claims priority benefit of U.S. Provisional Patent Application Ser. No. 60/741,307, filed Dec. 1, 2005.

### FIELD OF INVENTION

The present invention relates to a photoluminescent phosphor comprising an inorganic phosphor having a coating of oxide that renders the phosphor resistant to water-induced degradation.

### BACKGROUND OF THE INVENTION

Disclosed are, among other things, an microencapsulation method and an microencapsulated formulation that protects phosphor particles from moisture attack. As used herein, the term “microencapsulation,” “microencapsulated” or “microencapsulate” means relating to, containing or forming a layer of materials on the surfaces of individual phosphor grains or particles so as to form coated phosphors. The base phosphors that can be encapsulated include sulfur-containing materials such as metal thiogallate photoluminescent phosphors (including, for example, and without limitation, strontium thiogallate (STG) phosphors) and metal sulfide photoluminescent phosphors (including, for example, and without limitation, strontium calcium sulfide (SCS) phosphors). The encapsulated phosphor particles can be in the light path of a LED (light emitting diode) chip to form a lighting device emitting any of a large color gamut, including white light. The phosphors, such as STG:Eu and SCS:Eu, for example and without limitation, can convert part of the primary emission of the LED from blue color into green and red emissions, respectively, to form white light.

Metal thiogallate and metal sulfide photoluminescent phosphors can provide excellent photoluminescent phosphors for use in light-emitting devices, especially blue-emitting LEDs, for which one seeks to modify the color yield to include longer wavelengths. However, these phosphors can be susceptible to degradation caused by water or water vapor, and thus, moisture. It can be possible to protect the phosphors from moisture by appropriately embedding them on the LED, for example, in a polymer, such as an epoxy. Nonetheless, production and handling of such protected phosphors may be more complex than desirable.

The coating technique described in U.S. Pat. No. 6,811,813 now has been used with, for example, SCS phosphors, which provides some protection from moisture. However, hydrolytic chemical deposition techniques have been found to provide good to unexpectedly better protection—despite the use of water in the coating technique. A hydrolytic chemical vapor deposition (CVD) has been described for other phosphors, primarily electroluminescence phosphors, for example, in U.S. Pat. No. 5,958,591, but nothing indicates that such methods can produce a stable coated metal thiogallate or metal sulfide photoluminescent phosphor. As used herein, the phrase “stable coated” means having a significant resistance against moist environments to maintain function of the coated phosphor for a long period of time, e.g., about 200 hours.

It has now been discovered that, for example, and without limitation, the otherwise extremely moisture sensitive SCS phosphors can be protected from moisture to markedly enhance their commercial utility through hydrolytic coating methods. In some implementations, the phosphors (e.g., SCS phosphors) are protected such that they lose little, if any, of their initial photoluminescence over lengthy periods when subjected to highly stressed, humid conditions. An unlimited example of such conditions and such periods is a condition of about 85° C. and about 85% relative humidity for a period from about 16 hours to about 100 hours.

### SUMMARY OF THE INVENTION

In certain embodiments, the invention provides, among other things, a phosphor coated with a coating of oxide, the phosphor comprising (1) an inorganic phosphor selected from a metal thiogallate phosphor and a metal sulfide phosphor, and (2) a coating comprising at least one layer, where the layer comprises at least one oxide. The layer(s) of the coating render the phosphor relatively more resistant to water-induced degradation as compared to an uncoated phosphor. That is to say, the layer(s) of the coating increases the resistance of the phosphor to degradation stimulated by water (in all its forms), such as, for example, without limitation, the coated phosphor maintains about 80% of its original optical performance after exposure to about 85° C. and about 85% relative humidity for about 100 hours.

For example, in certain embodiments, the photoluminescent phosphor of the present invention comprises:
(a) an inorganic phosphor having one of the following formulas:
   (a) M1(Ga, Al)₂S₄:A.x(Ga, Al)₂S₃ Ia;
   (b) M1₂SiS₄:A Ib;
   (c) M1Si₂S₅:A Ic;
   (d) M2(S, Se):A,X IIa;
   (e) M2S:A,X IIb; or
   (f) M2SiO₄X:A IIIc;
   wherein, if present in the formula:
      A is at least one activator cation;
      M1 is at least one metal ion selected from Ca²⁺, Sr²⁺, Ba²⁺, Zn²⁺ and Y³⁺;
      M2 is at least one metal ion selected from Ca²⁺, Sr²⁺, Ba²+ and Cd²⁺;
      x is 0 to 0.2; and
      X is either at least one halide in atomic or ionic form or absent; and
(b) at least one layer of a coating on the inorganic phosphor, wherein the layer comprises at least one oxide. In certain embodiments, the inorganic phosphor is a particle; in certain embodiments, the inorganic phosphor is a grain.

In certain embodiments, the inorganic phosphor of the photoluminescent phosphor of the present invention has one of the following formulas:
(a) M1(Ga, Al)₂S₄:A.x(Ga, Al)₂S₃ Ia;
(b) M1Ga₂S₄:A. xGa₂S₃ Id;
(c) M2(S, Se):A,X IIa; or
(d) M2S:A,X IIb;
where M1, M2, A, x, and X are as previously defined. In certain embodiments, M1 is Ca²⁺, Sr²⁺ or a combination thereof; and M2 is Ca²⁺, Sr²⁺ or a combination thereof.

In certain embodiments of the photoluminescent phosphor of the present invention, the inorganic phosphor is a metal thiogallate phosphor, a metal chalcogenide phosphor or analog thereof. As used herein, the term “chalcogenide” refers to a binary chemical compound consisting of a heavy chalcogen, such as sulfur, selenium, and telluride, and an element more electropositive than the the chalcogen, such as Group III, IV and V elements from the periodic table of chemical elements. In certain embodiments, the metal thiogallate phosphor has a formula of:
(a) M1(Ga, Al)₂S₄:A.x(Ga, Al)₂S₃ Ia; or
(b) M1Ga₂S₄:A.xGa₂S₃ Id;
where A, M1 and x are as previously defined. In certain embodiments, the metal chalcogenide phosphor has a formula of M2(S, Se):A,X (IIa), where A and X are as previously defined, M2 comprises at least one metal ion selected from Ca²⁺, Sr²⁺, Ba²⁺ and Cd²⁺.

In certain embodiments, the Ga/Al component of an inorganic phosphor of formula Ia of the present invention can be all gallium, all aluminum, or a combination thereof. In certain embodiments, the S/Se component of an inorganic phosphor of formula IIa of the present invention can be all sulfur, all selenium, or a combination thereof.

In certain embodiments, the activator cation, A, is Eu²⁺, Cu²⁺, Cu⁺, Yb²⁺, Mn²⁺, Bi⁺, Bi³⁺, Sb³⁺, Pb²⁺, La³⁺, Ce³⁺, Pr³⁺, Nd³⁺, Sm³⁺, Eu³⁺, Gd³⁺, Tb³⁺, Dy³⁺, Ho³⁺, Er³⁺, Tm³⁺, Yb³⁺ or Lu³⁺. In certain embodiments, an Eu cation, such as Eu²⁺ or Eu³⁺, is used with one or more coactivators (i.e., an activator cation different than another activator cation, such as one or more of the aforementioned activators).

In certain embodiments, the inorganic phosphor of the photoluminescent phosphor of the present invention is a metal thiogallate phosphor having the formula: M1Ga₂S₄:A.xGa₂S₃ (Id), where M1, A and x are as previously defined.

In certain embodiments of the photoluminescent phosphor of the present invention, M1 is at least one metal ion selected from Ca²⁺, Sr²⁺ and a combination thereof.

In certain embodiments, the inorganic phosphor of the photoluminescent phosphor of the present invention is a metal sulfide phosphor having the formula: M2S:A,X (IIb), wherein M2, A and X are as previously defined.

In certain embodiments of the photoluminescent phosphor of the present invention, M2 is at least one metal ion selected from Ca²⁺, Sr²⁺ and a mixture thereof.

In certain embodiments, X is present, i.e., at least one halide in atomic or ionic form is present in the inorganic phosphor of the photoluminescent phosphor of the present invention.

In certain embodiments, the oxide of the coating of the photoluminescent phosphor of the present invention is titanium oxide, aluminum oxide, zirconium oxide, tin oxide, boron oxide, silicon oxide, zinc oxide, germanium oxide, aluminum silicate, Al₈BSi₃O₁₉(OH), B₂Al₂(SiO₄)₂(OH), ZnAl₂O₄, Al₂SiO₅, Al₄(SiO₄)₃, ZrSiO₄, or combinations thereof. In certain embodiments, the oxide is titanium oxide, aluminum oxide or silicon oxide.

In certain embodiments, the coating of the inorganic phosphor of the photoluminescent phosphor of the present invention has at least two layers. In certain embodiments, each layer independently comprises an oxide chosen from titanium oxide, aluminum oxide, silicon oxide and a combination thereof. In certain embodiments, one layer of the coating comprises titanium oxide.

In certain embodiments, the coating of the inorganic phosphor of the photoluminescent phosphor of the present invention is continuous.

In certain embodiments, the inorganic phosphor of the photoluminescent phosphor of the present invention comprises Eu²⁺ (i.e., A is Eu²⁺).

The present invention further provides a lighting device comprising: a LED producing light output (i.e., a LED that emits light) of wavelengths of at least 300 mn; and a coated photoluminescent phosphor according to the present invention, where the photoluminescent phosphor is situated to absorb at least a portion of the light output from the LED and effectively modifies the chromaticity of the light absorbed from the LED, resulting in it emitting light of a longer wavelength than that of the light absorbed from the LED. As used herein, the phrase “a portion of the light output” refers to a fraction of optical energy, or a fraction of photons, emitted from the LED. For example, and without limitation, more than about 50% of the emitted optical energy from the LED is absorbed by the phosphor. In certain embodiments, the LED emits light in the near ultraviolet (UV) range (e.g., about 400 nm) or the blue range (e.g., about 450 nm). In certain embodiments, the coated photoluminescent phosphor modifies the chromaticity of the absorbed portion of LED-emitted light into green light (e.g., about 540 nm) or red light (e.g., about 630 nm). In certain embodiments, the coated photoluminescent phosphor modifies the chromaticity of the absorbed portion of LED-emitted light into light of about 550 nm.

In certain embodiments, the lighting device of the present invention, can, for example, comprise a gallium nitride-based LED with a light-emitting layer comprising a quantum well structure. The lighting device can include a photoluminescent phosphor of the present invention and a reflector located so as to direct light from the LED or the coated photoluminescent phosphor. The coated photoluminescent phosphor of the present invention can be located on the surface of the LED or separated therefrom. The lighting device can further include a translucent material encapsulating (meaning enclosing or covering) the LED (or portion thereof from which the light output emerges) and the photoluminescent phosphor.

Additionally provided by the present invention is a method of coating a phosphor comprising: (a) providing a phosphor that is an inorganic phosphor selected from a metal thiogallate phosphor and a metal sulfide phosphor, and (b) exposing the phosphor to oxide precursors and water to yield at least one layer of coating that renders the phosphor relatively more resistant to water-induced degradation than when it is uncoated (e.g., the coated phosphor maintains about 80% of its original optical performance after exposure to 85° C. and 85% relative humidity for about 100 hours). The method of coating coats particles and grains of phosphor.

### BRIEF DESCRIPTION OF THE DRAWINGS

FIGS. 1-2 illustrate coated photoluminescent phosphors of the present invention.

FIGS. 3-5 show light emitting devices that can be used with the invention.

FIG. 6 shows a LED that can be used with the invention.

FIGS. 7 and 8 show measures of phosphor protection under stressed conditions.

FIG. 9A provides a top view of an exemplary lighting device, while FIG. 9B shows a side view of the same device.

FIG. 10 shows emission spectra for devices of FIG. 9 with different amounts of phosphor.

### DEFINITIONS

As used herein, “activator cation” refers to an ion that determines the wavelength of light emission from the phosphor of which the activator cation is a part.

As used herein, a “coating,” “oxide coating,” or “coating of oxide” refers to a covering or outside layer(s) comprising (a) at least one oxide (e.g., amorphous or crystalline), (b) lacks optically distinguishable embedded particles, and (c) is sufficiently complete as to provide relative protection against water, such as, a coating that maintains about 80% of a phosphor's original optical performance after exposure to about 85° C. and about 85% relative humidity for about 16 hours to about 100 hours. Such coatings can contain other elements and compounds, such as, those originating in the coating precursor (i.e., antecedent or predecessor) materials or phosphor particles. Accordingly, “oxide,” as used herein, refers to such materials that comprise metal or semiconductor cations and oxygen, which often is the primary material of the coating.

As used herein, “particle” refers to an individual crystal of phosphor.

As used herein, “grain” refers to an agglomeration, aggregation, polycrystalline or polymorph of phosphor particles, where the particles are not easily separated as compared to phosphor particles of a powder.

Temperatures described herein for processes involving a substantial gas phase are of the oven or other reaction vessel in question, not of the reactants per se.

“White light,” as used herein, is light of certain chromaticity values (e.g., Commission Internationale de l'Êclairage (CIE)), which are well-known in the art.

### DETAILED DESCRIPTION

Methods of making metal thiogallate phosphors are described, for example, in U.S. Pat. Nos. 6,544,438 and 7,018,565, and U.S. Published Patent Applications Nos. 2004/206936 and 2006/012287. Methods of making SCS phosphors are described, for example, in U.S. Pat. No. 6,783,700. Phosphor precursor amounts can be varied as would be recognized by those of ordinary skill in the art to obtain the phosphors used in the coating methods of the present invention. A phosphor precursor can be a metal carbonate, a metal nitrate, a metal oxide, a metal halide or a mixture thereof. Without limitation, any class of STG or SCS phosphor described in these patent publications can be coated as described herein. Examples of sulfur-containing phosphors that can be coated and applied to LEDs to make lighting devices of the present invention include, for example, and without limitation:
CaS:Bi⁺, Na⁺ (blue-emitting),
CaS:Ce³⁺ (yellow-emitting),
CaS:Cu⁺,Na⁺ (blue-emitting),
CaS:Eu²⁺ (red-emitting),
CaS:La³⁺ (blue-green-emitting),
CaS:Pb²⁺, Mn²⁺ (orange-emitting),
CaS:Sb³⁺ (orange-emitting),
CaS:Sb³⁺, Na⁺ (orange-emitting),
SrS:Ce³⁺ (green-emitting),
SrS:Cu⁺,Na⁺ (green-emitting),
SrS:Eu²⁺ (red-emitting),
SrS:Mn²⁺ (green-emitting),
Sr_{α}Ca_{1-α}S:Eu²⁺ (orange- or orange-red-emitting, α=01),
Sr_{β}Ca_{1-β}S:Ce³⁺ (yellow- or yellow-green-emitting, β=01),
Sr_{γ}Ca_{1-γ}S:Pb²⁺, Mn²⁺ (orange- or orange-yellow-emitting, y=0-1),
Zn_{ε1}Cd_{1-ε1}S:Cu⁺, Al³⁺ (ε1=0-1) (green or yellow-emitting),
Zn_{ε2}Cd_{1-ε2}S:Ag⁺, Cl⁻ (ε2=0-1) (blue or green-emitting),
Zn(S, Se):Cu⁺, Ag⁺,
MgS:Eu²⁺ (orange-emitting),
CaGa₂S₄:Ce³⁺ (blue-green-emitting),
CaGa₂S₄:Eu²⁺ (green-emitting),
CaGa₂S₄:Mn²⁺ (red-emitting),
CaGa₂S₄:Pb²⁺ (red-emitting),
ZnGa₂S₄:Mn²⁺ (red-emitting),
SrGa₂S₄:Pb²⁺ (orange-emitting),
BaAl₂S₄:Eu²⁺ (blue-emitting),
SrGa₂S₄:Ce³⁺ (blue-green-emitting),
SrGa₂S₄:Eu²⁺ (green-emitting),
Sr_{δ}Ca_{1-δ}Ga₂S₄:Eu²⁺ (green- or green-yellow-emitting, δ=0-1),
Ca₂SiS₄:Eu²⁺,
Ca₃SiO₄Cl₂:Eu,
Sr₂SiS₄:Eu²⁺ (green-emitting),
Ba₂SiS₄:Eu²⁺,
SrSi₂S₅:Eu²⁺,
BaSi₂S₅:Eu²⁺,
SrAl₂S₄:Eu²⁺, and
CaAl₂S₄:Eu²⁺.

The above-listed metal thiogallate phosphors can contain a portion of metal sulfide. Exemplary useful phosphor combinations are green-emitting strontium thiogallate phosphors activated with europium and red-emitting strontium sulfide phosphors activated with europium for use with blue-emitting or near UV-emitting LEDs.

In one embodiment, the phosphor particles are coated by agitating or suspending them so that all sides have substantially equal exposure (i.e., the majority, e.g., about ≧50% of the surfaces of the phosphor particles are exposed) to certain coating vapor or liquid during the period of the coating operation. For example, and without limitation, the particles can be suspended in a fluidized bed, or agitated or stirred in a liquid. Gas used to fluidize the particles can include the vapor used to coat the particles. For example, and without limitation, the gas can include an inert gas carrier (i.e., a gas that is non-reactive under normal circumstances) and the coating vapor. Carrier gas can be passed through vessel(s) of predominately (i.e., principally, for the most part or primarily, such as, ≧about 60%) liquid or solid form precursor to carry away vapor for use in the coating. The vessel(s) and connecting pathways can be heated as needed to maintain sufficient vapor pressure.

Where two or more oxide precursors are used in forming the same coating layer, carrier gas can be passed separately through vessels of the separate precursors and mixed prior to, or in, the coating reaction chamber of a reaction vessel. Relative carrier gas flow rates through the separate vessels can be adjusted to carry the desired amount of precursor in light of vapor pressure or empirical coating results. Water vapor is carried similarly to the reaction vessel, with an amount moderated similarly, as appropriate. In liquid-mediated coating methods, any number of dispensing methods can be used to incorporate multiple precursors into the liquid.

Coating can be accomplished through a hydrolysis to form a surface oxide, with the hydrolysis occurring in a vapor phase and/or in a liquid phase. An example of the former is chemical vapor deposition (CVD), while of the latter is a sol-gel process.

In vapor phase deposition reactions (i.e., a hydrolytic deposition reaction), the uncoated phosphor particles can be floated by a carrier gas in a reaction chamber to disperse the particles as substantially single particles (e.g., more than 95 percent (>95%) of the particles have no association, agglomeration or aggregation). The chamber can be heated to an appropriate temperature given the reactants (e.g., in some implementations, about 200° C.). Coating precursor materials in the vapor phase then are introduced into the chamber. Under the temperature conditions, at least a portion of precursor (e.g., about 20%) is decomposed hydrolytically to form an oxide layer on the surfaces of the phosphor particles, thereby microencapsulating them. A typical hydrolysis that can be used in the present invention is as follows:
TiCl₄+2H₂O→TiO₂+4HCl.

In liquid phase depositions (i.e., a hydrolytic deposition reaction), an uncoated phosphor powder can be suspended in an inert fluid medium (i.e., a medium having a limited ability to react chemically) containing coating precursor. The powder is stirred such that the particles are dispersed sufficiently so as to form a suspension and have little probability to form an agglomerate. As used herein, “suspension” refers to a colloidal mixture wherein one substance (i.e., the dispersed medium) is finely dispersed within another substance (i.e., the dispersion medium). A small amount of water then can be added to the suspension to initiate hydrolysis. If needed, the reaction is accelerated by an elevated temperature, e.g., about 70° C. The hydrolysis results in a formation of an oxide coating on the surfaces of the phosphor particles. For example, the following reaction can be used for coating SiO₂ on SCS particles:
Si(OC₂H₅)₄+2H₂O→SiO₂+4C₂H₅OH.

Oxides useful in the present invention are, for example, and without limitation, titanium oxides (e.g., TiO₂), aluminum oxide (e.g., Al₂O₃), zirconium oxide (e.g., ZrO₂), tin oxides (e.g., SnO₂), boron oxide (e.g., B₂O₃), silicon oxide (e.g., SiO₂), zinc oxide (e.g., ZnO), germanium oxide (e.g., GeO₂), tantalum oxide (e.g., Ta₂O₅), niobium oxide (e.g., Nb₂O₅), hafnium oxide (e.g., HfO₂), gallium oxide (e.g., Ga₂O₃), and the like. Further oxides useful in the present invention include oxides formed with more than one type of cation, for example, aluminum silicate [such as, 3Al₂O₃.2SiO₂ or in mullite form], Al₈BSi₃O₁₉(OH) [such as, in dunortierite form], B₂Al₂(SiO₄)₂(OH) [such as, in euclase form], ZnAl₂O₄ [such as, in gahnite form], Al₂SiO₅ [such as, in sillimanite form], ZrSiO₄ [such as, in zircon form], and the like. In certain embodiments, for use in the method of the present invention, volatile or appropriately soluble precursors that hydrolytically generate the oxides are used. Such precursors are known in the art.

In certain embodiments, the oxide layer of the coating of the present invention comprises predominantly (e.g., ≧about 60%) one type of oxide (as determined by the metal or semiconductor component), e.g., layer of titanium oxide, aluminum oxide, or silicon oxide. In certain embodiments, the coating of the present invention comprises two or more layers that are predominantly one type of oxide. For example, the layers can be made separately of two or more titanium oxides, aluminum oxides, or silicon oxides. In certain embodiments, one layer of the coating of the present invention is of silicon oxide, and another is of a titanium oxide or aluminum oxide.

Volatile precursors include, for example, and without limitation, halogenated metals (e.g., titanium tetrachloride (TiCl₄) and silicon tetrachloride (SiCl₄)), alkylated metals (e.g., trimethylaluminum, (Al(CH₃)₃), trimethylboron (B(CH₃)₃), tetramethylgermanium, Ge(CH₃)₄ and tetraethylzirconium, Zr(C₂H₅)₄, mixed halo (i.e., comprising fluorine, chlorine, bromine, iodine or astatine) and alkyl derivatives of metals (e.g., dimethylaluminum chloride, diethyldichlorsilane), metal or semiconductor alkoxide (e.g., titanium (IV) methoxide and tetraethylorthosilicate (TEOS)). With the aid of vapor water, these compounds can be hydrolyzed to yield their respective oxides. As used herein, “halogenated metals” refers to metal cations and anions of group VII elements of the periodic table of chemical elements that are ionically or valently bonded As used herein, “alkylated metals” refers to metal cations and anions comprising at least one C₁ to C₁₆ straight or branched moiety, such as, methyl, diethyl, propyl, isopropyl, butyl, tert-butyl, pentyl, hexyl, octyl, nonyl and decyl. As used herein, “alkyl” refers to a saturated hydrocarbon group that is unbranched (i.e., straight-chained) or branched (i.e., non-straight chained). Example alkyl groups, without limitation, include methyl (Me), ethyl (Et), propyl (e.g., n-propyl and isopropyl), butyl (e.g., n-butyl, isobutyl, t-butyl), pentyl (e.g., n-pentyl, isopentyl, neopentyl), and the like. In certain embodiments of the present invention, an alkyl group can contain from about 1 to about 10, from about 2 to about 8, from about 3 to about 6, from about 1 to about 8, from about 1 to about 6, from about 1 to about 4, from about 1 to about 3 carbon atoms, or from about 1, 2, 3, 4, 5, 6, 7, 8, 9 or 10 carbon atoms. As used herein, “alkoxide” refers to an alkyl-O— moiety, wherein alkyl is as previously defined.

Soluble precursors include, for example, metal or semiconductor alkoxides, (e.g. titanium (IV) methoxide and zirconium (IV) butoxide). Such compounds can form oxides by hydrolysis.

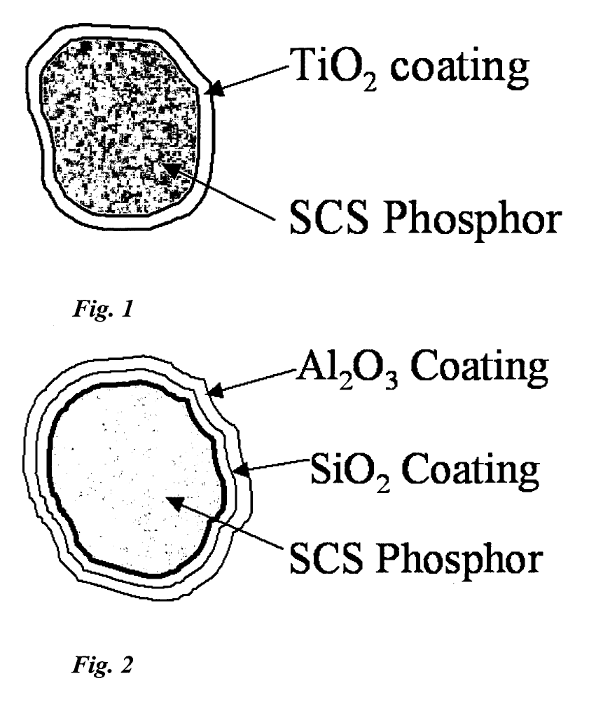

In certain embodiments, the coating of the present invention can be a single layer of one type of oxide, for example, a titanium oxide (FIG. 1); or, the coating can be multi-layer, i.e., comprising more than one layer or at least two layers, with the layers, independently of each other, comprising a different type of oxide or oxide combination, for example, one layer can comprise an aluminum oxide and one layer can comprise a silicon oxide (FIG. 2).

In certain embodiments of the present invention, the method of coating a phosphor comprises a hydrolytic deposition reaction, where the hydrolytic deposition reaction is conducted at a temperature selected (in light of the given phosphor) to retain useful fluorescence (e.g., having an optical performance of about ≧80% of its uncoated version). The temperature of a vapor phase deposition can be, for example, from about 25° C. to about 400° C. The temperature can be, for example, at least about 25° C., at least about 50° C., at least about 75° C., at least about 100° C., at least about 150° C., or at least about 200° C. The temperature can be, for example, at most about 400° C., at most about 300° C., at most about 275° C., at most about 250° C., at most about 225° C., or at most about 200° C. The temperature of a liquid phase deposition can be, for example, from about 25° C. to about 90° C., depending on the reactants, the solvent, and the stability of the phosphor to the temperature. The temperature can be, for example, at least about 25° C., at least about 30° C., at least about 35° C., at least about 40° C., at least about 45° C., at least about 50° C., at least about 55° C., at least about 60° C., at least about 65° C., or at least about 70° C. The temperature can be, for example, at most about 90° C., at most about 85° C., at most about 80° C., at most about 75° C., at most about 70° C., at most about 65° C., at most about 60° C., at most about 55° C., or at most about 50° C. The temperature is, of course, lower than the boiling point of the solvent at the operative pressure.

In certain embodiments, the coating of the present invention can be substantially transparent (such that useful fluorescence is retained) and are typically between about 0.1 micron and about 3.0 microns thick or between about 0.05 micron and about 0.50 micron thick. Coatings that are too thin (e.g., at least less than about 0.005 micron (5 nm) thick) can tend to provide insufficient impermeability to moisture, i.e., the coating fails to provide a phosphor protection from moisture whereby the phosphor degrades and loses its photoluminescence. Coatings that are too thick (e.g., greater than about 3.0 microns thick) can tend to be less transparent and result in reduced brightness of the coated phosphor.

In certain embodiments, the mole percentage of activator cation A is about 0.001% to about 10%. In certain embodiments, the range of the mole percentage of A is from one of the following lower endpoints (inclusive or exclusive): about 0.001%, about 0.01%, about 0.02%, about 0.05%, about 0.1%, about 0.2%, about 0.5%, about 1%, about 2%, about 3%, about 4% and about 5% mole and from one of the following upper endpoints (inclusive or exclusive): about 0.01%, about 0.02%, about 0.05%, about 0.1%, about 0.2%, about 0.5%, about 1%, about 2%, about 3%, about 4%, about 5% and about 10% mole. For example, the range can be from about 0.01% to about 5% mole. It will be understood by those of ordinary skill in the art that A can in fact substitute for the primary (i.e., principal or main) metal components of the phosphor—nonetheless, the primary metal components, if recited in relative amounts, are recited normalized, as if the combined primary metals were present in formula amounts as would pertain absent A.

For STG or SCS phosphors, in certain embodiments of the present invention, the primary metals M1 or M2 can be present as Sr_{y}Ca_{1-y}, where 0<y<1. For example, y can be at least about 0.01, at least about 0.02, at least about 0.05, at least about 0.10, at least about 0.15, at least about 0.20, at least about 0.25, at least about 0.30, at least about 0.35, at least about 0.40, at least about 0.45, at least about 0.50, at least about 0.55, at least about 0.60, at least about 0.65, at least about 0.70, at least about 0.75, at least about 0.80, at least about 0.85, at least about 0.90, or at least about 0.95; or y can be at most about 0.99, at most about 0.98, at most about at most 0.95, at most about 0.90, at most about 0.85, at most about 0.80, at most about 0.75, at most about 0.70, at most about 0.65, at most about 0.60, at most about 0.55, at most about 0.50, at most about 0.45, at most about 0.40, at most about 0.35, at most about 0.30, at most about 0.25, at most about 0.20, at most about 0.15, at most about 0.10, or at most about 0.05.

The amount of halide X also can affect the actual empirical formula—but consistent with conventions in the phosphor art, the mineral component of the formula is written without consideration of this effect. The mole % of X can be, for example, at least about 0.5%, at least about 1%, at least about 2%, or at least about 5%; or the mole % of X can be at most about 30%, at most about 20%, at most about 10%, or at most about 5%. As used herein, and consistent with conventions in the phosphor art, “halide” refers to a crystalline material comprised of metal cations and anions of Group VII elements that are bonded ionically.

In certain embodiments, the amount of protection provided by the coating of the present invention can be measured by the amount of original emission intensity retained over a period of time at about 85° C. and about 85% humidity. In certain embodiments, the coated photoluminescent phosphors retain at least about 40%; at least about 45%; at least about 50%; at least about 55%; at least about 60%; at least about 65%; at least about 70%; at least about 75%; at least about 80% photoluminescence when subjected to these conditions for at least about 30 mins., at least about 1 hour, or at least about 2 hours. In certain embodiments, the coated photoluminescent phosphors retain at least about 40%; at least about 45%; at least about 50%; at least about 55%; at least about 60%; at least about 65%; at least about 70%; at least about 75%; or at least about 80% of original emission intensity when subjected to these conditions for at least about 4 hours; at least about 8 hour; at least about 12 hours; at least about 16 hours; at least about 24 hours; at least about 48 hours; or at least about 96 hours.

The disclosed phosphor products can be used to make white LED lamps, such as, lamps seeking to deliver a high color rendering index (CRI>about 75), a high efficiency (>about 80%) and long lifetimes (>about 10,000 hrs.), which are unachievable with existing phosphor products. In certain embodiments, the light source of the present invention (e.g., a white LED lamp) delivers a high CRI of at least about 84, a high efficiency of at least about 90% and long lifetimes of at least about 100,000 hours.

In certain embodiments, the emission peak for a photoluminescent phosphor of the present invention is measured with the emission wavelength source being lit at about 440 nm±about 100 nm. In certain embodiments, the emission range for a phosphor of the present invention is, for example, and without limitation, from one of the following lower endpoints (inclusive or exclusive) of: about 380 nm, about 381 nm, about 382 nm, about 383 nm, and each one nm increment up to about 799 nm and from one of the following upper endpoints (inclusive or exclusive) of: about 800 nm, about 799 nm, about 798 nm, about 797 nm, and each one nm down to about 381 nm. In certain embodiments, the lower endpoint of the emission range are, for example, and without limitation, about 400 nm, about 401 nm, about 402 nm, and each one nm increment up to about 799 nm.

In certain embodiments, the excitation peak range for a phosphor of the present invention is, for example, and without limitation, from one of the following lower endpoints (inclusive or exclusive) of: about 200 nm, about 201 nm, about 202 nm, about 203 nm, and each one nm increment up to about 549 nm and from one of the following upper endpoints (inclusive or exclusive): about 550 nm, about 549 nm, about 548 nm, about 547 nm, and each one nm down to about 201 nm.

In certain embodiments, the present invention provides a lighting device comprising a light source and a photoluminescent phosphor of the present invention. As used herein, “light source” refers to a Group III-V semiconductor quantum well-based light emitting diode or a phosphor other than the photoluminescent phosphor of a lighting device of the present invention. When used in a lighting device, it will be recognized that the photoluminescent phosphors of the present invention can be excited by light from a primary source, such as, a semiconductor light source (e.g., a LED) emitting in the wavelength range of about 250 nm to about 500 nm or about 300 nm to about 420 nm, or from a secondary light source, such as, emissions from other phosphor(s) that emit in the wavelength range of about 250 nm to about 500 nm or about 300 nm to about 420 nm. Where the excitation light is secondary, in relation to the photoluminescent phosphors of the present invention, the excitation-induced light is the relevant source light. Devices that use the photoluminescent phosphor of the present invention can include, for example, and without limitation, mirrors, such as, dielectric mirrors, which direct light produced by the photoluminescent phosphors of the present invention to the light output, rather than direct such light to the interior of the device (such as, the primary light source).

The semiconductor light source (e.g., a LED) can, in certain embodiments, emit light of at least about 250 nm, at least about 255 nm, at least about 260 nm, and so on in increments of about 5 nm to at least about 500. The semiconductor light source can, in certain embodiments, emit light of at most about 500 nm, at most about 495 nm, at most about 490 nm, and so on in increments of about 5 nm to or less about 300 nm.

In certain embodiments of the present invention, photoluminescent phosphors of the present invention can be dispersed in the lighting device with a binder, a solidifier, a dispersant, a filler or the like. The binder can be, for example, and without limitation, a light curable polymer, such as, an acrylic resin, an epoxy resin, a polycarbonate resin, a silicone resin, a glass, a quartz and the like. The photoluminescent phosphor of the present invention can be dispersed in the binder by methods known in the art. For example, in some cases, the photoluminescent phosphor can be suspended in a solvent with the polymer suspended, dissolved or partially dissolved in the solvent, thus forming a slurry, which then can be dispersed on the lighting device and the solvent evaporated therefrom. In certain embodiments, the phosphor can be suspended in a liquid, such as, a pre-cured precursor to the resin to form a slurry, the slurry then can be dispersed on the lighting device and the polymer (resin) cured thereon. Curing can be, for example, by heat, UV, or a curing agent (such as, a free radical initiator) mixed with the precursor. As used herein “cure” or “curing” refers to, relates to or is a process for polymerizing or solidifying a substance or mixture thereof, often to improve stability or usability of the substance or mixture thereof. In certain embodiments, the binder used to disperse the phosphor particles in a lighting device can be liquefied with heat, thereby, a slurry is formed, and then the slurry is dispersed on the lighting device and allowed to solidify in situ. Dispersants (meaning a substance that promotes the formation and stabilization of a mixture (e.g., a suspension) of one substance into another) include, for example, and without limitation, titanium oxides, aluminum oxides, barium titanates, silicon oxides, and the like.

In certain embodiments, the lighting device of the present invention comprises a semiconductor light source, such as a LED, to either create excitation energy, or to excite another system to thereby provide the excitation energy for the photoluminescent phosphor of the present invention. Devices using the present invention can include, for example, and without limitation, white light producing lighting devices, indigo light producing lighting devices, blue light producing lighting devices, green light producing lighting devices, yellow light producing lighting devices, orange light producing lighting devices, pink light producing lighting devices, red light producing lighting devices, or lighting devices with an output chromaticity defined by the line between the chromaticity of a photoluminescent phosphor of the present invention and that of at least one second light source. Headlights or other navigation lights for vehicles can be made with the lighting devices of the present invention. The lighting devices can be output indicators for small electronic devices, such as cell phones and personal digital assistants (PDAs). The lighting devices of the present invention also can be the backlights of the liquid crystal displays for cell phones, PDAs and laptop computers. Given appropriate power supplies, room lighting can be based on devices of the invention. The warmth (i.e., amount of yellow/red chromaticity) of lighting devices of the present invention can be tuned by selection of the ratio of light from a photoluminescent phosphor of the present invention to light from a second source (including, a second photoluminescent phosphor of the present invention).

Suitable semiconductor light sources for use in the present invention also are any that create light that excites the photoluminescent phosphors of the present invention, or that excites a different phosphor that in turn excites the photoluminescent phosphors of the present invention. Such semiconductor light sources can be, for example, and without limitation, GaN (gallium nitride) type semiconductor light sources, In—Al—Ga—N type semiconductor light sources (InᵢAlⱼGaₖN, where i+j+k=about 1, where two or more of i, j and k can be 0), BN, SiC, ZnSe, BAlGaN, and BinAlGaN light sources, and the like. The semiconductor light source (e.g., a semiconductor chip) can be based, for example, on III-V or II-VI quantum well structures (meaning structures comprising compounds that combine elements of the periodic table of the chemical elements from Group III with those from Group V or elements from Group II with those from Group VI). In certain embodiments, a blue or a near ultraviolet (UV) emitting semiconductor light source is used.

In certain embodiments, for a semiconductor light source of the lighting device of the present invention that has at least two different phosphors, it can be useful to disperse the phosphors separately, and superimpose the phosphors as layers instead of dispersing the phosphors together in one matrix. Such layering can be used to obtain a final light emission color by way of a plurality of color conversion processes. For example, the light emission process is: absorption of the light emission of a semiconductor light source by a first photoluminescent phosphor of the present invention, light emission by the first photoluminescent phosphor, absorption of the light emission of the first photoluminescent phosphor by a second phosphor, and the light emission by the second phosphor. In certain embodiments, the second phosphor is a photoluminescent phosphor of the present invention.

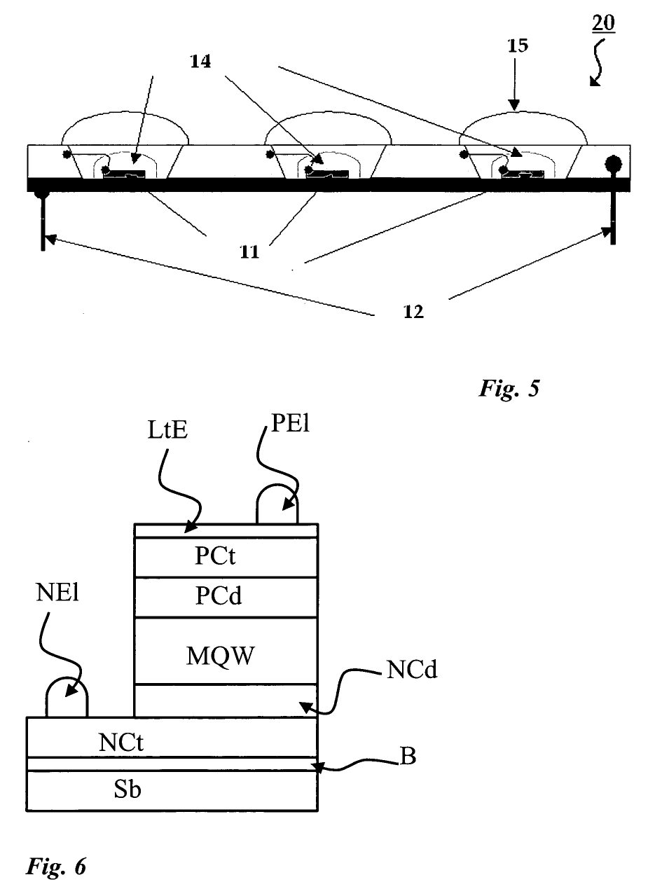

FIG. 6 shows an exemplary layered structure of a semiconductor light source. The semiconductor light source comprises a substrate Sb, such as, for example, a sapphire substrate. For example, a buffer layer B, an n-type contact layer NCt, an n-type cladding layer NCd, a multi-quantum well active layer MQW, a p-type cladding layer PCd, and a p-type contact layer PCt are formed in that order as nitride semiconductor layers. The layers can be formed, for example, by organometallic chemical vapor deposition (MOCVD) on the substrate Sb. Thereafter, a light-transparent electrode LtE is formed on the whole surface of the p-type contact layer PCt, a p electrode PEl is formed on a part of the light-transparent electrode LtE, and an n electrode NEl is formed on a part of the n-type contact layer NCt. These layers can be formed, for example, by sputtering or vacuum deposition.

The buffer layer B can be formed of, for example, AlN, and the n-type contact layer NCt can be formed of, for example, GaN.

The n-type cladding layer NCd can be formed, for example, of AlᵣGa₁₋ᵣN where 0≦r<1, the p-type cladding layer PCd can be formed, for example, of Al_{q}Ga_{1-q}N where 0<q<1, and the p-type contact layer PCt can be formed, for example, of AlₛGa₁₋ₛN wherein 0≦s<1 and s<q. The band gap of the p-type cladding layer PCd is made larger than the band gap of the n-type cladding layer NCd. The n-type cladding layer NCd and the p-type cladding layer PCd each can have a single-composition construction, or can have a construction such that the above-described nitride semiconductor layers having a thickness of not more than about 100 angstroms and different from each other in composition are stacked on top of each other so as to provide a super-lattice structure. When the layer thickness is not more than about 100 angstroms, the occurrence of cracks or crystal defects in the layer can be prevented.

The multi-quantum well active layer MQW can be composed of a plurality (i.e., at least two) of InGaN well layers and a plurality of GaN barrier layers. The well layer and the barrier layer can have a thickness of not more than about 100 angstroms, such as, for example, about 60 angstroms to about 70 angstroms, so as to constitute a super-lattice structure. Since the crystal of InGaN is softer than other aluminum-containing nitride semiconductors, such as, AlGaN, the use of InGaN in the layer constituting the active layer MQW can offer an advantage that all the stacked nitride semiconductor layers are less likely to crack. The multi-quantum well active layer MQW can also be composed of a plurality of InGaN well layers and a plurality of AlGaN barrier layers. Or, the multi-quantum well active layer MQW can be composed of a plurality of AlInGaN well layers and a plurality of AlInGaN barrier layers. In this case, the band gap energy of the barrier layer can be made larger than the band gap energy of the well layer.

In certain embodiments, the light source of the present invention comprises a reflecting layer on the substrate Sb side from the multi-quantum well active layer MQW, for example, on the buffer layer B side of the n-type contact layer NCt. The reflecting layer also can be provided on the surface of the substrate Sb remote (i.e., at a distance) from the multi-quantum well active layer MQW stacked on the substrate Sb. The reflecting layer can have a maximum reflectance with respect to light emitted from the active layer MQW and can be formed of, for example, aluminum, or can have a multi-layer structure of thin GaN layers. The provision of the reflecting layer can permit light emitted from the active layer MQW to be reflected from the reflecting layer, can reduce the internal absorption of light emitted from the active layer MQW, can increase the quantity of light output toward above (i.e., going out of the device, or a direction toward the outside world and away from the substrate), and can reduce the incidence of light on the mount for the light source to prevent deterioration.

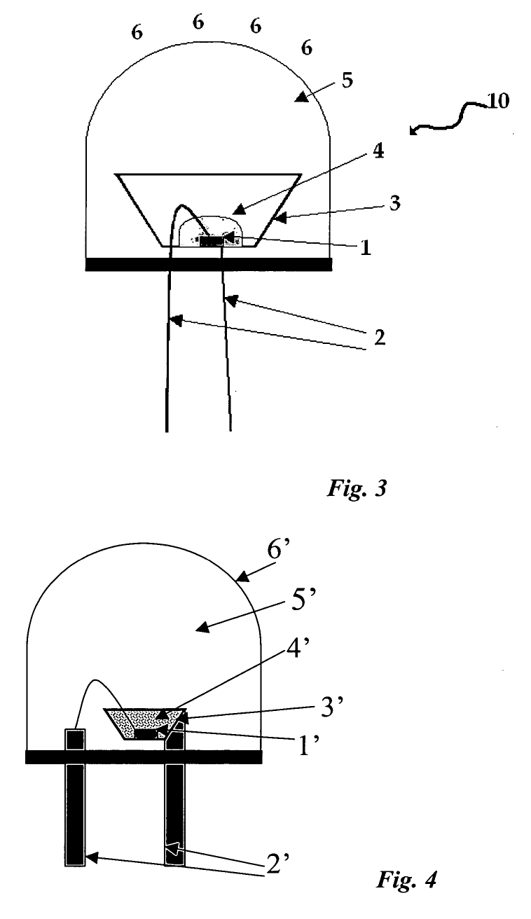

Shown in FIGS. 3-5 are some exemplary structures of the lighting device of the present invention comprised of a LED and phosphors. FIG. 3 shows a light emitting device 10 with an LED chip 1 (i.e., primary light source) powered by leads 2, and having phosphor-containing material 4 secured between the LED chip and the final light output 6. A reflector 3 can serve to concentrate light output. A transparent envelope 5 can isolate the LED chip and phosphor from the environment and/or provide a lens. FIG. 4 shows a light emitting device 10′ with a LED chip 1′ powered by leads 2′, and having phosphor-containing material 4′ secured between the LED chip and the final light output 6′, in this case above reflector 3′. The reflector, and the location of the phosphor-containing material away from the LED chip, can serve to concentrate final light output. A transparent envelope 5′ can isolate the LED chip and phosphor from the environment and/or provide a lens. The lighting device 20 of FIG. 5 has multiple LED chips 11, leads 12, phosphor-containing material 14, and transparent envelope 15.

The leads 2, 2′, 12 can comprise thin wires supported by a thicker lead frame or the leads can comprise self-supported electrodes and the lead frame can be omitted. The leads provide current to the LED chip, and thus, cause the LED chip to emit radiation.

It will be understood by those of ordinary skill in the art that there are any number of ways to associate phosphors with a semiconductor light source (e.g., a LED light source) such that light from the semiconductor light source is managed by its interaction with the phosphors. U.S. Published Patent Applications Nos. 2004/0145289 and 2004/0145288 illustrate lighting devices where a phosphor is positioned away from the light output of the semiconductor light sources. U.S. Published Patent Application No. 2004/0159846 further illustrates, without limitation, lighting devices that can be used in the present invention.

Semiconductor light source-based white light devices can be used, for example, in a self-emission type display for displaying a predetermined pattern or a graphic design on a display portion of an audio system, a household appliance, a measuring instrument, a medical appliance, and the like. Such semiconductor light source-based light devices also can be used, for example, and without limitation, as light sources of a back-light for a liquid crystal diode (LCD) display, a printer head, a facsimile, a copying apparatus, and the like.

Unless defined otherwise, all technical and scientific terms used herein have the same meaning as commonly understood by one of ordinary skill in the art to which this invention belongs. All technical and scientific terms used herein have the same meaning when used. It must be noted that, as used herein and in the appended claims, the singular forms “a”, “and”, and “the” include plural references unless the context clearly dictates otherwise.

### EXAMPLES

The following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g., amounts, temperature, etc.), but an account for some experimental errors and deviations should be made. Unless indicated otherwise, parts are parts by weight, molecular weight is average molecular weight, and temperature is in degrees Centigrade.

### Example 1

### Preparation of SiO₂-coated Sr_{0.85}Ca_{0.15}S:Eu,F

Part A. Preparation of Calcium Sulfate

Calcium carbonate (about 300 grams) was stirred with water, and nitric acid was added to dissolve the carbonate salt. A slight excess of calcium carbonate was added to provide a solution having a pH≧about 5. The resultant calcium nitrate solution was milky in appearance.

Magnesium metal pieces (about 1.5 grams) were cleaned with dilute (e.g., about 0.01 to 0.5 N) nitric acid, rinsed and added to the calcium nitrate solution to remove metallic impurities. This mixture was heated to about 85° C. while stirring, and then allowed to cool. The solution was filtered until clear.

Sulfuric acid (about 180 mL, about 51 mol %) was slowly added to the nitrate solution, and the mixture stirred during precipitation of the calcium sulfate. The mixture was stirred for about two hours at a temperature of about 60° C.

The liquid was decanted and the solids rinsed with water until the solids were free of acid. A final rinse with methanol was done to assist in drying the solids, which was carried out in an oven at about 100° C. overnight.

Part B. Preparation of Strontium Sulfate

Strontium sulfate was prepared using a procedure substantially like that for calcium sulfate as described above in Example 1, Part A; however strontium carbonate was used as a strontium source.

Part C. Preparation of the Strontium Calcium Sulfide Phosphor

Strontium sulfate (about 0.85 mole) prepared as described in Example 1, Part B, hereinabove, was mixed with about 0.15 mole of calcium sulfate that was made in Example 1, Part A (described above) together with europium oxide dissolved in dilute (e.g., about 0.01 to 0.5 N) nitric acid, and then slurried. The slurry was dried at about 100° C. overnight. The resultant mixed solids were ground with a mortar and pestle.

The mixed solids were fired in a mixture of gaseous H₂/N₂, a forming gas, at about 1100° C. for about four hours. After cooling, the strontium calcium sulfide phosphor product was ground and re-fired in the forming gas at about 1100° C. for about four hours. The product then was ground with a mortar and a pestle.

Part D. Fluorination

A fluoride source (e.g., ammonium fluoride) was added to and well mixed with the phosphor product of Example 1, Part C. The resultant solid mixture was fired at about 300° C. in N₂ gas for about one hour, where the temperature of the N₂ gas can be, for example, from about 300° C. to about 600° C. The fluorinated product then was ground and sieved through an about 100 mesh screen.

Part E. Sol-Gel Coating with SiO₂

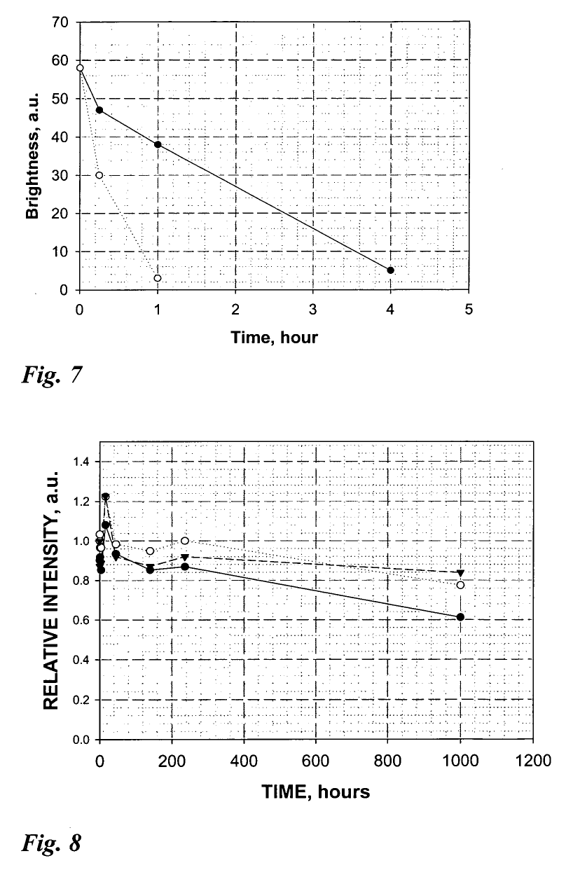

The fluorinated phosphor product of Example 1, Part D (about 100 grams) was suspended in about 340 grams of 2-propanol containing about 34 grams of tetraethoxysilane. The suspension was sonicated for about 10 minutes. Water (about 24 grams) with a pH=about 8.0 (adjusted with ammonium hydroxide) was added to the suspension. The suspension then was incubated and stirred for about 16 hours. The solid was filtered out and dried at about 50° C. for about 4 hours. The resultant powder was baked at about 150° C. under N₂ gas for about 1 hour. Then the coated photoluminescent phosphor was kept at about 85° C. and about 85% relative humidity as a stability test. The fluorescent emission of a tested sample of the coated photoluminescent phosphor was measured at different times. Fluorescent emission was measured using a SPEX-1680 Fluorimeter (ISA Company, Edison, N.J.), using a xenon lamp (at about 460 nm) to excite the tested sample and a photo multiplier to detect the emission. FIG. 7 shows the results for a coated (solid circles) and an uncoated (open circles) phosphor.

### Example 2

### Preparation of SiO₂-coated SrGa₂S₄:Eu.0.07Ga₂S₃ (STG)

Part A. Making STG Phosphor

A solution of gallium nitrate was prepared as follows: about 57.45 parts of gallium were dissolved in about 400 mL concentrated nitric acid. The solution was heated until brown fumes appeared, at which time the heat was removed and the container covered. After standing overnight, the resultant green solution was heated and alternately cooled until it turned yellow, and then clear. Deionized water was added to form about 1000 mL of solution.

Ammonium hydroxide (about 180 mL) slowly was added to obtain a solution with a pH of about 2.0. Water was added to make up about 1200 mL of the solution.

Europium oxide (about 2.815 parts) was dissolved in about 400 ml of dilute (e.g., about 0.01 to about 0.5 N) nitric acid. Strontium carbonate slowly was added, adding more nitric acid if needed. About 1.2 ml of an about 0.01 M solution of praseodymium oxide also was added, and water was added to make up about 600 ml of a strontium-europium-praseodymium nitrate solution.

Ammonium sulfate (about 120 parts) was added with stirring to the strontium-europium-praseodymium nitrate solution. The mixture was stirred for about ten minutes, and acidified to a pH of about 1.4. The gallium nitrate solution was added, and the pH raised to about 7 with ammonium hydroxide. The mixture was stirred for about two hours and allowed to stand overnight.

The supernatant solution was decanted and filtered and the precipitate washed with acetone. The precipitate was re-suspended in about 2500 ml of acetone, stirring for about 1 hour at about 50° C., and then filtered. The re-suspension step was repeated, and the precipitate dried overnight at about 55° C.

The dried precipitate then was ground and fired at about 800° C. in hydrogen sulfide for about five hours. The resulting green phosphor was ground and re-fired at about 900° C. for about two hours. The phosphor then was ground further and sieved.

Part B. Coating SiO₂

The phosphor product of Example 2, Part A (about 100 grams) was suspended in about 340 grams of 2-propanol containing about 34 grams of tetraethoxysilane. The suspension was sonicated for about 10 minutes. Water (about 24 grams) with a pH=about 8.0 (adjusted with ammonium hydroxide) was added to the suspension. The suspension then was incubated and stirred for about 16 hours. The solid was filtered out and dried at about 50° C. for about 4 hours. The resultant powder was baked at about 150° C. under N₂ gas for about 1 hour. The coated photoluminescent phosphor product was incubated at about 85° C. and about 85% relative humidity.

### Example 3

### Preparation of LED White Light Device

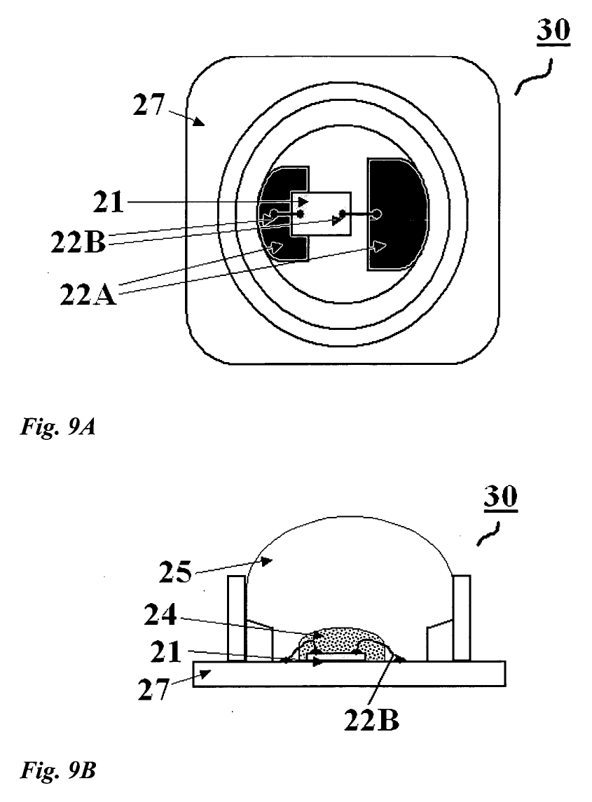

A white light device 30 was made as a surface mount type of device using a semiconductor light emitting diode (LED) 21 (FIG. 9). The LED had an InGaN semiconductor quantum well structure emitting at about 460 nm. As assembled into the white light device, the about 460 nm light is converted partially to green light by the SiO₂-coated SrGa₂S₄:Eu.0.07Ga₂S₃ described in Example 2, and partially to red light by a TiO₂—SiO₂-coated Sr_{0.85}Ca_{0.15}S:Eu,F phosphor. These phosphors were provided in a phosphor layer 24.

To make the device, a p-type semiconductor layer and an n-type semiconductor layer were formed in the light emitting diode, and electrically conductive leads 22B were linked with ohmic electrodes 22A. Insulating sealing materials comprising a portion of transparent package 25 were formed so as to cover the outer peripheral of the metal electrode and prevent short circuits. The device was mounted on a support 27.

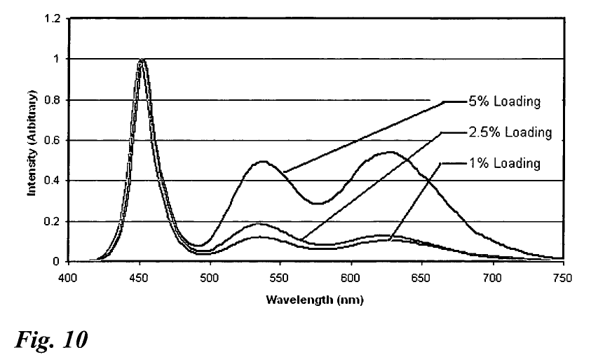

To form the phosphor layer, the two coated photoluminescent phosphors, STG and SCS, were mixed into a slurry with a silicone resin material (e.g., SR-7010, Dow Coming, Midland, Mich.). The slurry was applied onto the LED chip 21, which was mounted on the support structure 27. The slurry then was cured at about 150° C. to form a hard and transparent protection window. Three different devices, with different phosphor loads, were made. The phosphor loads in the slurry were about 1 wt %, about 2.5 wt % and about 5 wt %, based on the total weight of the phosphor composition. The emission spectra of the devices are shown in FIG. 10.

Publications and references, including but not limited to patents and patent applications, cited in this specification are herein incorporated by reference in their entirety in the entire portion cited as if each individual publication or reference were specifically and individually indicated to be incorporated by reference herein as being fully set forth. Any patent application to which this application claims priority also is incorporated by reference herein in the manner described above for publications and references.

While this invention has been described with an emphasis upon some embodiments, it will be obvious to those of ordinary skill in the art that variations in the embodiments can be used and that it is intended that the invention can be practiced otherwise than as specifically described herein. Accordingly, this invention includes all modifications encompassed within the spirit and scope of the invention as defined by the claims that follow.

What is claimed:

1. A photoluminescent phosphor comprising:
a. an inorganic phosphor having one of the following formulas:
i. M1(Ga, Al)₂S₄:A.x(Ga, Al)₂S₃ Ia;
ii. M1₂SiS₄:A Ib;
iii. M1Si₂S₅:A Ic;
iv. M2(S, Se):A,X IIa;
v. M2S:A,X IIb; or
vi. M2SiO₄X:A IIIc;
wherein, if present in the formula:
A is at least one activator cation;
M1 is at least one metal ion selected from Ca²⁺, Sr²⁺, Ba²⁺, Zn²⁺ and Y³⁺;
M2 is at least one metal ion selected from Ca²⁺, Sr²⁺, Ba²⁺ and Cd²⁺;
x is 0 to 0.2; and
X is either at least one halide in atomic or ionic form or absent; and
b. at least one layer of a coating on the inorganic phosphor, wherein the layer comprises at least one oxide;

2. The photoluminescent phosphor of claim 1, wherein A is Eu²⁺, Cu²⁺, Cu⁺, Yb²⁺, Mn²⁺, Bi⁺, Bi³⁺, Sb³⁺, Pb²⁺, La³⁺, Ce³⁺, Pr³⁺, Nd³⁺, Sm³⁺, Eu³⁺, Gd³⁺, Tb³⁺, Dy³⁺, Ho³⁺, Er³⁺, Tm³⁺, Yb³⁺ or Lu³⁺.

3. The photoluminescent phosphor of claim 1, wherein the coating is continuous.

4. The photoluminescent phosphor of claim 1, wherein the oxide is titanium oxide, aluminum oxide, zirconium oxide, tin oxide, boron oxide, silicon oxide, zinc oxide, germanium oxide, aluminum silicate, Al₈BSi₃O₁₉(OH), B₂Al₂(SiO₄)₂(OH), ZnAl₂O₄, Al₂SiO₅, Al₄(SiO₄)₃, ZrSiO₄, or a combination thereof.

5. The photoluminescent phosphor of claim 1, wherein the oxide of the coating is titanium oxide, aluminum oxide or silicon oxide.

6. The photoluminescent phosphor of claim 1, wherein the coating on the inorganic phosphor comprises at least two layers.

7. The photoluminescent phosphor of claim 6, wherein each layer independently comprises an oxide selected from titanium oxide, aluminum oxide, silicon oxide and a combination thereof.

8. The photoluminescent phosphor of claim 7, wherein one layer comprises titanium oxide.

9. The photoluminescent phosphor of claim 1, wherein the photoluminescent phosphor retains about 40% or more of its original emission intensity when maintained at about 85° C. and about 85% relative humidity for about 4 hours.

10. The photoluminescent phosphor of claim 1, wherein the photoluminescent phosphor retains about 40% or more of its original emission intensity when maintained at about 85° C. and about 85% relative humidity for about 96 hours.

11. The photoluminescent phosphor of claim 10, wherein the oxide comprises titanium oxide.

12. The photoluminescent phosphor of claim 11, wherein the oxide comprises silicon oxide.

13. The photoluminescent phosphor of claim 1, wherein the inorganic phosphor has one of the following formulas:
a. M1(Ga, Al)₂S₄:A.x(Ga, Al)₂S₃ Ia;
b. M1Ga₂S₄:A.xGa₂S₃ Id;
c. M2(S, Se):A,X IIa; or
d. M2S:A,X IIb.

14. The photoluminescent phosphor of claim 13, wherein:
a. M1 is Ca²⁺, Sr²⁺ or a combination thereof; and
b. M2 is Ca²⁺, Sr²⁺ or a combination thereof.

15. The photoluminescent phosphor of claim 14, wherein A is Eu²⁺.

16. The photoluminescent phosphor of claim 13, wherein the oxide comprises titanium oxide.

17. The photoluminescent phosphor of claim 16, wherein the oxide comprises silicon oxide, aluminum oxide or a combination thereof.

18. The photoluminescent phosphor of claim 1, wherein the inorganic phosphor is:
a. CaS:Bi⁺, Na⁺;
b. CaS:Ce³⁺;
c. CaS:Cu⁺, Na⁺;
d. CaS:Eu²⁺;
e. CaS:La³⁺;
f. CaS:Pb²⁺, Mn²⁺;
g. CaS:Sb³⁺;
h. CaS:Sb³⁺, Na⁺;
i. SrS:Ce³⁺;
j. SrS:Cu⁺, Na⁺;
k. SrS:Eu²⁺;
l. SrS:Mn²⁺;
m. Sr_{α}Ca_{1-α}S:Eu²⁺, wherein α=0-1;
n. Sr_{β}Ca_{1-β}S:Ce³⁺, wherein β=0-1;
o. Sr_{γ}Ca_{1-γ}S:Pb²⁺, Mn²⁺, wherein γ=0-1;
p. Zn_{ε1}Cd_{1-ε1}S:Cu⁺, Al³⁺, wherein ε1=0-1;
q. Zn_{ε2}Cd_{1-ε2}S:Ag⁺, Cl⁻, wherein ε2=0-1;
r. Zn(S, Se):Cu⁺, Ag⁺;
s. MgS:Eu²⁺;
t. CaGa₂S₄:Ce³⁺;
u. CaGa₂S₄:Eu²⁺;
v. CaGa₂S₄:Mn²⁺;
w. CaGa₂S₄:Pb²⁺;
x. ZnGa₂S₄:Mn²⁺;
y. SrGa₂S₄:Pb²⁺;
z. BaAl₂S₄:Eu²⁺;
aa. SrGa₂S₄:Ce³⁺;
bb. SrGa₂S₄:Eu²⁺;
cc. Sr_{δ}Ca_{1-δ}Ga₂S₄:Eu, wherein δ=0-1;
dd. Ca₂SiS₄:Eu²⁺;
ee. Ca₃SiO₄Cl₂:Eu²⁺;
ff. Sr₂SiS₄:Eu²⁺;
gg. Ba₂SiS₄:Eu²⁺;
hh. SrSi₂S₅:Eu²⁺;
ii. BaSi₂S₅:Eu²⁺;
jj. SrAl₂S₄:Eu²⁺; or
kk. CaAl₂S₄:Eu²⁺.

19. A lighting device comprising:
a. a light source that emits light at wavelengths of at least about 300 nm; and
b. a photoluminescent phosphor according to claim 1,
wherein:
i. the photoluminescent phosphor is capable of absorbing at least a portion of the light emitted from the light source;
ii. the photoluminescent phosphor modifies the chromaticity of the portion of the light absorbed from the light source; and
iii. the photoluminescent phosphor emits light of a longer wavelength than that of the light absorbed from the light source.

20. The lighting device of claim 19, wherein the lighting device produces white light.

21. The lighting device of claim 19, wherein the inorganic phosphor comprises the formula: M1Ga₂S₄:A:xGa₂S₃ (Ia)or M2S:A,X (IIb).

22. The lighting device of claim 19, wherein the light source is a LED.
